(19) United States
(12) Patent Application Publication
(10) Pub. No.: US 2025/0154661 A1
(43) Pub. Date: May 15, 2025

(54) ETCHING SOLUTION COMPOSITION AND ETCHING METHOD

(71) Applicant: KANTO KAGAKU KABUSHIKI KAISHA, Tokyo (JP)

(72) Inventors: Hiroki INAZUMI, Saitama (JP); Toshikazu SHIMIZU, Saitama (JP); Yuki YOSHIDA, Saitama (JP)

(21) Appl. No.: 18/833,165

(22) PCT Filed: Feb. 1, 2023
(86) PCT No.: PCT/JP2023/003145

§ 371 Date: Jul. 25, 2024

(30) Foreign Application Priority Data
Feb. 2, 2022 (JP) 2022-014642

(51) Int. Cl. C23F 1/26; H01L 21/306; H01L 21/3213

(52) U.S. Cl. CPC C23F 1/26; H01L 21/30604; H01L 21/32134

(57) ABSTRACT

An object of the invention is to provide an etching solution composition which adds an excellent etched surface morphology to a metal to be etched at a suppressed etch rate. The invention relates to an etching solution composition in which the etching solution composition contains (A) nitric acid, (B) acetic acid, (C) nitrilotris(methylene phosphonic acid), (D) a halogen compound and (E) water.

### TECHNICAL FIELD

The present invention relates to an etching solution composition and an etching method using the etching solution composition.

### BACKGROUND ART

Recently, the processing speeds and the capacities of electronic devices have been significantly improved, and in particular, the memory capacities have been increased by employing a three-dimensional structure, as in a 3D NAND-type flash memory, in which memory devices are stacked vertically on a flat silicon surface. Since the capacity of a 3D HAND-type flash memory depends on the number of the layers and the like, examination for further increasing the number of the layers has still been made continuously.

In the current 3D NAND-type flash memory using tungsten for the thin gate film, however, it is concerned that the signals are delayed due to the reduction in the film thicknesses of the layers for the purpose of suppressing the increase in the size in the vertical direction caused by the increase in the number of the layers. To solve the problem, the resistance of the thin gate film material may be made lower, and examination is made to substitute the tungsten electrode with a molybdenum (Mo) electrode for the thin gate film material in the next generation devices. To produce a 3D NAND-type flash memory using a molybdenum electrode and having a high aspect structure (the number of the layers is extremely large), an etching solution which can create a desired three-dimensional structure elaborately is required.

PTL 1 discloses a production method of a touch panel sensor including a process of selectively etching a predetermined pattern on Al, an Al alloy, Ag, or an Ag alloy using a metal-layer etching solution containing water, phosphoric acid, nitric acid, and acetic acid.

PTL 2 discloses a liquid composition for etching copper or a metal compound containing copper as the main component formed on IGZO which contains (A) hydrogen peroxide, (B) a fluorine atom-free acid, (C) one kind or more of compound selected from the group consisting of a phosphonic acid, a phosphoric acid ester, 1H-tetrazole-1-acetic acid, 1H-tetrazole-5-acetic acid and 4-amino-1,2,4-triazole and (D, water, PTL 3 discloses a liquid composition for etching copper or a metal compound containing copper as the main component formed on IGZO which contains (A) hydrogen peroxide, (B) a fluorine atom-free acid, (C) a fluorine ion source, UD) one kind or more of compound selected from the group consisting of aminotri(methylene phosphonic acid), N,N,N′,N′-ethylenediaminetetrakis(methylene phosphonic acid), diethylenetriaminepenta(methylene phosphonic acid), bis(hexamethylene)triaminepenta(methylene phosphonic acid) and pentaethylenehexamineocta(methylene phosphonic acid), (E) a hydrogen peroxide stabilizer and (F) water.

PTL 4 discloses an etching solution composition for hatch etching treatment of a tungsten film and a titanium nitride film which contains nitric acid and water.

PTL 5 discloses an etching solution suitable for both a tungsten-containing metal and a TiN-containing material which contains an oxidizer, a fluorine containing etching compound, an organic solvent, a chelating agent, a corrosion inhibitor, and a surfactant.

PTL 6 discloses an etching solution composition which contains hydrogen peroxide, an etch inhibitor, a cheating agent, an etch additive, an oxide semiconductor protective agent and a pH regulator and which is characterized in that the oxide semiconductor protective agent is contained at 0.1 to 3 wt % based on the total weight of the composition.

PTL 7 discloses an etching solution composition which is used for etching metal films having at least one layer of thin metal film of molybdenum or a molybdenum alloy and which contains phosphoric acid, nitric acid, a polyalkylene polyamine containing three amino groups or more per molecule and water.

PTL 8 discloses a technique directed to a method for forming a conductive pattern, including forming a first conductive layer and a second conductive layer on a substrate, in which the first conductive layer is titanium nitride, the second conductive layer is tungsten, the first conductive layer and the second conductive layer are etched using an etching solution composition containing phosphoric acid, nitric acid, an assistant oxidant and water in which hydrogen peroxide, acetic acid, a hydroxide and hydrofluoric acid are not present in the etching solution composition), and the etching solution composition has substantially the same etching rate for the metal nitride and the second metal.

PTL 9 discloses a method for etching a metal barrier layer and a metal layer for forming the metal barrier layer and the metal layer on a substrate which uses an etching solution composition containing a certain oxidant, an etching inhibitor including a compound expressed by a formula (1) and a certain metal oxide solubilizer.

### CITATION LIST

### Patent Literature

PTL 1: JP2012-164079A
PTL 2: JP2016-108659A
PTL 3: JP2016-111342A
PTL 4: JP2018-006718A
PTL 3: JP2019-165228A
PTL 6: JP2019-165240A
PTL 7: JP2013-237873A
PTL 8: US 2015/0200112A1
PTL 9: U.S. Pat. No. 11,028,488 B2

### SUMMARY OF INVENTION

### Technical Problem

Although various etching solution compositions have been developed as described above, an etching solution composition which can form a better pattern is required. Therefore, considering the conventional problems, an object of the invention is to provide an etching solution morphology to a metal to be etched at a suppressed etch rate. Another object of the invention is to provide a production method of the etching solution composition and an etching method using the etching solution composition.

### Solution to Problem

The present inventors have found that an etching solution composition in which the etching solution composition contains (A) nitric acid, (B) acetic acid, (C) nitrilotris(methylene phosphonic acid), (D) a halogen compound and (E) water adds an excellent etched surface morphology to a metal to be etched at a suppressed etch rate, and as a result of further research, the invention has been completed.

That is, the invention relates to the followings.

[1] An etching solution composition,
in which the etching solution composition contains (A) nitric acid, (B) acetic acid, (C) nitrilotris(methylene phosphonic acid), (D) a halogen compound and (E) water.

[2] The etching solution composition according to [1], in which the concentration of the halogen compound (D) is higher than 0.05 M based on the etching solution composition.

[3] The etching solution composition according to [1] or [2], in which the etching solution composition further contains (F) 1-hydroxyethane-1,1-diphosphonic acid.

[4] The etching solution composition according to any one of [1] to [3], in which the halogen compound (D) is a chloride.

[5] The etching solution composition according to any one of [1] to [4], in which the etching solution composition contains no peroxide.

[6] The etching solution composition according to any one of [1] to [5], etching solution composition which is for etching treatment of molybdenum or a metal containing molybdenum.

[7] The etching solution composition according to any one of [1] to [6] which is for creating a pattern having a three-dimensional structure.

[8] A method for forming a recess, in which the method includes a step of treating with the etching solution composition according to any one of [1] to [7].

[9] An etching method using the etching solution composition according to any one of [1] to [7], in which the temperature of the etching solution composition is 15 to 50° C.

### Advantageous Effects of Invention

According to the invention, an etching solution composition which adds an excellent etched surface morphology to a metal to be etched at a suppressed etch rate can be provided.

In particular, in the case where the etching solution composition of the invention is used for producing a 3D NAND-type flash memory in which many thin gate films containing molybdenum and many insulating films are alternately stacked, even when the aspect ratio of a unit cell is large, the thin gate films can be etched in the entire unit cell with a nearly even recess amount (etch amount), and the morphology of the thin gate film surface after etching becomes excellent.

That is, since the composition of the invention contains water at a predetermined concentration, the composition not only adds an excellent etched surface morphology but also enables etching of the top layer and the bottom layer with nearly even recess amounts (etch amounts) also in a multi-layer laminate.

Furthermore, by adjusting the amount of acetic acid or the like, the hazardous material compositions under the Fire Service Act can be avoided.

### BRIEF DESCRIPTION OF DRAWINGS

FIG. 1 is a schematic diagram of a substrate to be etched.

FIG. 2 includes (i) a schematic diagram of an etched test substrate and (ii) an enlarged schematic diagram of pairs of thin gate films and insulating films after etching treatment.

### DESCRIPTION OF EMBODIMENTS

The invention is explained in detail below based on preferable embodiments of the invention.

The etching solution composition of the invention is an etching solution composition, and the etching solution composition contains (A) nitric acid, (B) acetic acid, (C) nitrilotris(methylene phosphonic acid), (D) a halogen compound and (E) water. The etching solution composition can add an excellent etched surface morphology to a metal to be etched at a suppressed etch rate.

In the present specification, the unit “M” means “mol/L”.

In the present specification, the numerical range “a to b” means “a or more and b or less”.

The etching solution composition of the invention contains (A) nitric acid, (B) acetic acid, (C) nitrilotris(methylene phosphonic acid), (D) a halogen compound and (E) water.

The nitric acid (A) is a component which oxidizes the metal to be etched and which contributes to the dissolution. The nitric acid (A) content is not particularly limited, and is preferably higher than 2.00 M based on the etching solution composition in view of smoothing the surface morphology. The content is more preferably higher than 2.00 M and 4.00 M or less, further preferably 2.50 to 3.50 M.

The acetic acid (B) is a component which contributes to a decrease in the water concentration of the etching solution composition. The acetic acid (B) content is not particularly limited, and is preferably 8.0 M or less, more preferably 7.8 M or less, further preferably 7.6 M in view of avoiding any hazardous material composition.

The nitrilotris(methylene phosphonic acid) (C) is considered to be adsorbed to the surface of the metal to be etched and to be able to suppress the dissolution reaction without changing the water concentration. Nitrilotris methylene phosphonic acid) is also referred to as NTMP in the present specification.

The nitrilotris(methylene phosphonic acid) (C) content is not particularly limited, and is preferably 0.1 to 1.2 M, more preferably 0.1 to 1.0 M, further preferably 0.1 to 0.8 M.

The halogen compound (D) is considered to form a complex with the metal to be etched, an oxide thereof or the like. Examples of the halogen compound include a fluoride, a chloride, a bromide, an iodide, an astatide. The fluoride is preferably HF or NH₄F. The chloride is preferably HCl, NH₄Cl, KCl or NaCl. The bromide is preferably HBr or NH₄Br. The iodide is preferably HI or NH₄I. The halogen compound is preferably a chloride.

The halogen compound (D) content is not particularly limited, and is preferably higher than 0.05 M based on the etching solution composition in view of the etched surface morphology, the top layer/bottom layer ratio or the like. The content is particularly preferably 0.06 to 1.00 M, more preferably 0.06 to 0.80 M, further preferably 0.06 to 0.50 M.

The water (E) is used as a solvent in the etching solution composition. The water (E) content is not particularly limited, and is preferably lower than 24.0 M. The content is more preferably 19.0 to 23.9 M, further preferably 19.5 to 23.5 M.

(F) 1-Hydroxyethane-1,1-diphosphonic acid may be further contained in the etching solution composition of the invention, 1-Hydroxyethane-1,1-diphosphonic acid is also referred to as HEDP in the present specification. The 1-hydroxyethane-1,1-diphosphonic acid (F) content is not particularly limited, and is preferably 0.35 to 1.20 M, more preferably 0.35 to 1.00 M, further preferably 0.35 to 0.80 M in view of suppressing the etch rate.

An optional component can be contained in the etching solution composition of the invention in addition to the components described above as long as the etching treatment of the metal as the subject is not prevented. Examples of the optional component which can be used in the invention include an organic solvent, a surfactant.

In an aspect, no peroxide is preferably contained in the etching solution composition of the invention. In an aspect, no hydrogen peroxide is preferably contained in the etching solution composition of the invention.

The metal to be etched with the etching solution composition of the invention is preferably molybdenum or a metal containing molybdenum.

It is not clear why an excellent etched surface morphology can be added to a metal to be etched at a suppressed etch rate when the etching solution composition of the invention is used, but the following mechanism may apply.

For example, when molybdenum is etched using a phosphoric acid+nitric acid+acetic acid-based etching solution, it is considered that the reaction advances as in the following chemical equations.

Mo+2HNO₃→MoO₂+NO₂+NO+H₂O (1)

MoO₂+HNO₂→MoO₃+HNO (2)

12MoO₃+H₃PO₄+6H₂O→H₃PMo₁₂O₄₀·6H₂O (3)

As shown in the equations above, since dissolution of molybdenum requires reaction with water in the end, the equation (3) becomes the limiting factor due to the decrease in the water concentration. The etch rate is considered to be suppressed as a result.

Regarding smoothing of the surface morphology after etching, molybdenum has various oxidation states, and compounds which easily dissolve in nitric acid, water or the like and compounds which do not easily dis-solve are mixed. When molybdenum molecules in various oxidation states with different solubility in nitric acid, water or the like are mixed, the smoothness of the surface morphology after etching tends to be deteriorated. On the other hand, it is considered as follows: when NTMP is physically adsorbed to the surface of molybdenum to be etched, coating film is formed; molybdenum in different oxidation states can be dissolved relatively evenly by dissolving together with the coating film; and as a result, smoothing of the surface morphology becomes possible.

It is considered that, since a halogen compound is contained in the etching solution composition, the physical adsorption of the NTMP can be promoted, and as a result, the etch rate can be suppressed significantly.

The invention also relates to a method for forming etching including a step of treating with the etching solution composition according to the invention.

The etching solution composition of the invention is preferably used for creating a pattern having a three-dimensional structure.

The etching solution composition of the invention can add an excellent etched surface morphology particularly to molybdenum or a metal containing molybdenum at a suppressed etch rate. As a result, when a 3D NAND-type f lash memory using thin gate film containing molybdenum and having a high aspect structure (the number of the layers is extremely large) is produced, a pattern having a three-dimensional structure can be created elaborately.

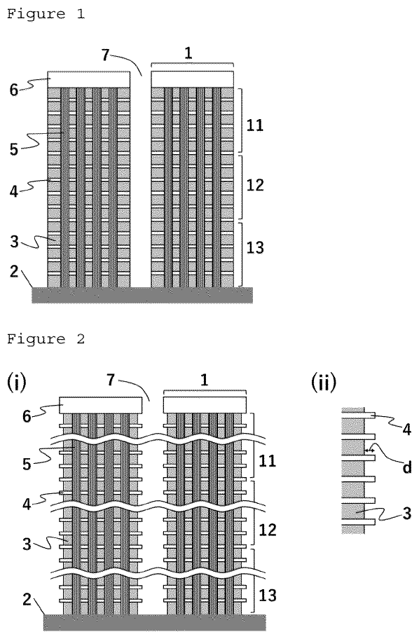

Preferable aspects of the invention are described in detail below referring to the schematic diagram of a substrate to be etched illustrated in FIG. 1.

The etching solution composition of the invention is preferably used for producing a 3D NAND flash memory from a substrate formed by alternately stacking thin gate films (wordlines) (3) and insulating films (element separation thin films between cells) (4) in the vertical direction on a Si substrate (2).

Of 3D NAND flash memories, the etching solution composition of the invention is particularly suitable for producing a 3D NAND flash memory having highly stacked layers or having a high aspect ratio of a unit cell (1). For example, when 128 flash memories are vertically stacked, at least 128 pairs of the thin gate film (3) and the insulating film (4) are formed.

When the etching solution composition of the invention is subjected to production of a 3D NAND flash memory, the subject to be etched is the thin gate films (3) of the alternately stacked films of the thin gate films (word lines) (3) and the insulating films (element separation thin films between cells) (in the vertical direction on the Si substrate (2).

It is needless to mention that the thin cate film (3) may contain another metal such as aluminum, magnesium, and calcium although molybdenum is the main component. Furthermore, the thin gate film (3) preferably contains molybdenum at 80 wt % or more, more preferably at 90 wt % or more, further preferably at 95 wt % or more.

The film thickness of the thin gate film (3) is preferably 100 to 7000 Å, more preferably 200 to 1000 Å, further preferably 200 to 500 Å.

Examples of insulating film (4) include SiO₂ film, Si₃N₄ film, and the film thickness of the insulating film (4) is preferably 100 to 7000 Å, more preferably 200 to 1000 Å, further preferably 200 to 500 Å.

When the etching solution composition of the invention is subjected to production of a 3D NAND flash memory, the subject particularly preferably has highly stacked layers of the thin gate films (3) and the insulating films (4). Specifically, one in which 64 pairs or more of the thin gate film (3) and the insulating film (4) are stacked is preferable, and one in which 128 pairs or more are stacked is more preferable. One in which 200 pairs or more are staked is further preferable.

A preferable subject to be etched with the etching solution composition of the invention is particularly one having a high ratio of the height (depth) and the diameter (aspect ratio) of the hole (7) in the unit cell (1) (a high aspect ratio), a height of the hole (7) of 2.5 to 10 μm, a diameter of 100 to 200 nm and height/diameter (ascent ratio) of the hole (7) of 12.5 to 100.

When a subject to be etched having such a high aspect ratio is dipped in the etching solution composition, the etching solution composition enters the opening of the hole (7) of the unit cell (1) towards the Si substrate (2) and then reaches the Si substrate (2). Therefore, the thin gate film (3) close to the opening of the hole (7) comes into contact with the etching solution composition earlier than the thin gate film (3) close to the Si substrate (2). Due to the time lag, the etch rate tends to differ with the position of the thin gate film (3) when the etch rate is determined from the dipping time and the etch amount.

On the other hand, since the etch rate of the etching solution composition of the invention is suppressed, etching advances without the difference in the etch rate described above even when the etching solution composition is used for a subject to be etched having a high aspect ratio.

For example, when the pairs of the thin gate films (3) and the insulating films (4) in the unit cell (1) are divided into three equal sections of a top layer (11), a middle layer (12) and a bottom layer (13) from the opening of the hole (7), the thin gate films (3) can be considered to be etched more evenly in the entire unit cell (1), as the ratio of the average recess amount of a plurality of points in the top layer (11) and the average recess amount of a plurality of points in the bottom layer (13) (also called “top layer/bottom layer ratio” below) is closer to 1. The top layer/bottom layer ratio is preferably 1.5 or less, more preferably 1.0 to 1.2, further preferably 1.0.

The method for producing an etching solution composition of the invention is not particularly restricted as long as it is in an aspect in which the etching solution composition is an etching solution composition and in which the etching solution composition is an etching solution composition containing (A) nitric acid, (B) acetic acid, (C) nitrilotris(methylene phosphonic acid), (D) a halogen compound and (E) water.

Preferable aspects of the components (A) to (E), the component (F), which may further be contained, and the optional component in the method for producing an etching solution composition of the invention are as described above.

The invention also relates to an etching method using the etching solution composition described above. The temperature (liquid temperature) of the etching solution composition during etching is 15 to 50° C., preferably 15 to 35° C., more preferably 20 to 30° C.

When the temperature of the etching solution composition of the invention during etching exceeds 50° C., suppression of the etch rate may not be possible, n particular, in the case of a subject to be etched having a high aspect ratio, the top layer/bottom layer ratio becomes large, and an elaborate three-dimensional structure may be difficult to create.

Preferable aspects of the components (A) to (E), the component (F), which may further be contained, and the optional component and preferable aspects of the metal to be etched in the etching method using an etching solution composition of the invention are as described above.

Although the invention has been explained in detail above based on preferable embodiments, the invention is not limited thereto. Each component can be replaced with any component that can exhibit a similar function, or an optional component can be added.

### EXAMPLES

The invention is shown with the Examples and the Comparative Examples below, and the contents of the invention are shown in further detail, but the invention is not limited to the Examples.

Etching solution compositions were prepared and evaluated as follows.

### [Preparation of Etching Solution Compositions]

Etching solution compositions were prepared with the concentrations shown in the tables below. The following materials were used as the components.
Nitric acid: manufactured by KANTO CHEMICAL CO., INC.
Acetic acid: manufactured by KANT CHEMICAL CO., INC.
Nitrilotris(methylene phosphonic acid): manufactured by Chelest Corporation
HCl: manufactured by KANTO CHEMICAL CO., INC,
NH₄Cl: manufactured by KANTO CHEMICAL CO., INC.
KCl: manufactured by KANTO CHEMICAL CO., INC.
NaCl: manufactured by KANTO CHEMICAL CO., INC.
1-Hydroxyethane 1,1-diphosphonic acid: manufactured by Tokyo Chemical Industry Co., Ltd.
Water: ultrapure water purified with an ultrapure water device system manufactured by Merck KGaA
H₃PO₄: manufactured by KANTO CHEMICAL CO., INC.
PBTC (2-phosphonobutane-1,2,4-tricarboxylic acid): manufactured by Chelest Corporation

### [Test Substrate]

Substrates of 15×15 mm were used as test substrates. A plurality of unit cells in which thin gate films containing molybdenum and insulating films composed of SiO₂ were alternately stacked were formed on the substrates.

### [Etching of Test Substrates]

The test substrates were dipped in 100 mL or the etching solution compositions of the Examples and the Comparative Examples. The dipping was conducted for 10 to 120 minutes under stirring conditions of about 200 rpm. Here, unless otherwise clearly stated in the tables below, the liquid temperature of the etching solution composition was maintained at 25° C. while the test substrate was dipped.

Subsequently, the test substrates that were taken out of the etching solution compositions were washed with deionized water and dried by blowing nitrogen gas, and thus etched test substrates were obtained.

### [Evaluation of Etch Rate and Top Layer/Bottom Layer Ratio]

The etched test substrates were cut in the middle, and the cross sections were observed using a field emission scanning electron microscope (FE-SEM: SU8220 manufactured by Hitachi High-Tech Fielding Corporation). Thus, the depths of etching in the thin gate films (the recess amounts: the lengths of etching in the parallel direction to the Si substrate) were measured. The contents of the measurement are described in detail referring to (i) the schematic diagram of an etched test substrate and (ii) the enlarged schematic diagram of pairs of thin gate films and insulating films after etching treatment illustrated in FIG. 2.

Pairs of thin gate films (3) and insulating films (4) of a unit cell (1) in each etched test substrate were divided into three equal sections of a top layer (11), a middle layer (12) and a bottom layer (13) from the opening of a hole (7), and recess amounts (d) of the thin gate films (3) were measured. Specifically, the recess amounts (d) of the chin gate films (3) were measured at 15 to 20 points each on the left and the right in each of the top layer (11), the middle layer (12) and the bottom layer (13) of one unit cell, and the averages thereof were used as the average recess amounts of the top layer (11), the middle layer (12) and the bottom layer (13).

The etch rates [nm/min.] were determined as the slopes of the lines derived from the relations between the average recess amounts of the top layer (11), the middle layer (12) and the bottom layer (13) and the dipping time of the test substrate.

Moreover, the top layer/bottom layer ratio was calculated by dividing the average recess amount of the top layer (11) by the average recess amount of the bottom layer (13).

### [Evaluation of Etched Surface Morphology]

The thin gate film surfaces of the test substrates after the etching treatment which were cut as described above were observed with image analysis software (ImageJ) and the morphology thereof was evaluated as follows.
∘ (Good): A smooth thin gate film surface was observed.
Δ (Slightly poor): A slightly rough thin gate film surface was observed.
x (Poor): A rough thin gate film surface was observed.

### Examples 1 to 4

The etching solution compositions of Examples 1 to 4

were prepared with the concentrations shown in the table below, and the test substrates were etched.

TABLE 1

| | | | | | | | | | | Top | |
|---|---|---|---|---|---|---|---|---|---|---|---|
| | | | | | Additive | | Etch Rate [nm/min.] | | | Layer/Bottom | Etched |
| | Concentration [M] | | | | | Concen- | Top | Middle | Bottom | Layer Ratio | Surface |
| | H₂O | HNO₃ | AcOH | NTMP | Compound | tration | Layer | Layer | Layer | [—] | Morphology |
| Example 1 | 19.6 | 3.0 | 6.8 | 0.8 | HCl | 0.1M | 0.3 | 0.3 | 0.2 | 1.3 | ◯ |
| Example 2 | 19.2 | 3.0 | 7.0 | 0.8 | NH₄Cl | 0.1M | 0.3 | 0.3 | 0.3 | 1.1 | ◯ |
| Example 3 | 19.2 | 3.0 | 7.0 | 0.8 | KCl | 0.1M | 0.2 | 0.2 | 0.2 | 1.2 | ◯ |
| Example 4 | 19.2 | 3.0 | 7.0 | 0.8 | NaCl | 0.1M | 0.3 | 0.3 | 0.3 | 1.1 | ◯ |

With the etching solution compositions of Examples 1 to 4, the top layer, the middle layer, and the bottom layer of the test substrate using thin gate films containing molybdenum could be etched with nearly even recess amounts. Moreover, the morphology of the thin gate film surface after the etching treatment was excellent.

### Examples 5 to 8

The etching solution compositions of Examples 5 to 8 which further contained (F) 1-hydroxyethane-1,1-diphosphonic acid (HEDP) were prepared with the concentrations shown in the table below, and the test substrates were etched,

TABLE 2

| | | | | | | | | | | | Top | |
|---|---|---|---|---|---|---|---|---|---|---|---|---|
| | | | | | | Additive | | Etch Rate [nm/min.] | | | Layer/Bottom | Etched |
| | Concentration [M] | | | | | | Concen- | Top | Middle | Bottom | Layer Ratio | Surface |
| | H₂O | HNO₃ | AcOH | NTMP | HEDP | Compound | tration | Layer | Layer | Layer | [—] | Morphology |
| Example 5 | 20.2 | 3.0 | 7.5 | 0.2 | 0.5 | HCl | 0.2M | 4.3 | 4.1 | 3.9 | 1.1 | ◯ |
| Example 6 | 20.1 | 3.0 | 7.6 | 0.2 | 0.5 | NH₄Cl | 0.2M | 2.8 | 2.7 | 2.6 | 1.1 | ◯ |
| Example 7 | 20.1 | 3.0 | 7.6 | 0.2 | 0.5 | KCl | 0.2M | 2.2 | 2.2 | 1.9 | 1.1 | ◯ |
| Example 8 | 20.2 | 3.0 | 7.7 | 0.2 | 0.5 | NaCl | 0.2M | 3.5 | 3.3 | 3.3 | 1.1 | ◯ |

With the etching solution compositions of Examples 5 to 8, the top layer, the middle layer, and the bottom layer of the test substrate using thin gate films containing molybdenum could be etched with nearly even recess amounts. Moreover, the morphology of the thin gate film surface after the etching treatment was excellent.

### Comparative Examples 1 to 33

The etching solution compositions of Comparative Examples 1 to 3 were prepared with the concentrations shown in the table below, and the test substrates were etched,

TABLE 3

| | | | | | | | | Top | |
|---|---|---|---|---|---|---|---|---|---|
| | | | | | Etch Rate [nm/min.] | | | Layer/Bottom | Etched |
| | Concentration [M] | | | | Top | Middle | Bottom | Layer Ratio | Surface |
| | H₂O | HNO₃ | AcOH | NTMP | Layer | Layer | Layer | [—] | Morphology |
| Comparative | 19.2 | 3.0 | 7.0 | 0.8 | 6.7 | 2.7 | 1.1 | 6.2 | ◯ |
| Example 1 | | | | | | | | | |
| Comparative | 18.6 | 2.5 | 7.5 | 0.8 | 5.3 | 1.1 | 0.0 | — | Δ |
| Example 2 | | | | | | | | | |
| Comparative | 19.9 | 2.0 | 7.4 | 0.8 | 1.3 | 0.0 | 0.0 | — | Δ |
| Example 3 | | | | | | | | | |

### Example 3

As shown in Comparative Examples 1 to 3, with the etching solution compositions which contained nitric acid, acetic acid, NTMP and water but did not contain any halogen compound, suppression of the etch rate was insufficient compared to that in Examples 1 to 8, and/or the etched surface morphology was A (slightly poor). It was thus found that the suppression and/or the etched surface morphology cannot be achieved even when the nitric acid concentration is decreased. This indicates that the halogen compound is important to obtain aimed etching performance.

### Comparative Examples 4 to 6

The etching solution compositions of Comparative Examples 4 to 6 were prepared with the concentrations shown in the table below, and the test substrates were etched.

TABLE 4

| | | | | | | | | | | Top | |
|---|---|---|---|---|---|---|---|---|---|---|---|
| | | | | | Additive | | Etch Rate [nm/min.] | | | Layer/Bottom | Etched |
| | Concentration [M] | | | | | Concen- | Top | Middle | Bottom | Layer Ratio | Surface |
| | H₂O | NH₄Cl | HNO₃ | AcOH | Compound | tration | Layer | Layer | Layer | [—] | Morphology |
| Comparative | 25.1 | 0.1 | 3.0 | 7.5 | H₃PO₄ | 0.8 | >100 | — | — | — | X |
| Example 4 | | | | | | | | | | | |
| Comparative | 20.9 | 0.1 | 3.0 | 7.6 | HEDP | 0.8 | >100 | >100 | >100 | — | ◯ |
| Example 5 | | | | | | | | | | | |
| Comparative | 18.0 | 0.1 | 3.0 | 7.4 | PBTC | 0.8 | >100 | — | — | — | X |
| Example 6 | | | | | | | | | | | |

As shown in Comparative Examples 4 to 6, it was found that, with the etching solution compositions which contained nitric acid, acetic acid, NH₄Cl as the halogen compound and water but did not contain NTMP, suppression of the etch rate was insufficient compared to that in Examples 1 to 8, and/or the etched surface morphology was x. This indicates that NTMP is important to obtain aimed etching performance.

### INDUSTRIAL APPLICABILITY

Using the etching solution composition of the invention, an excellent etched surface morphology can be added to a metal to be etched at a suppressed etch rate. The etching solution composition of the invention can be particularly preferably used for producing a 3D NAND-type flash memory in which many thin gate films containing molybdenum and many insulating films are alternately stacked.

### REFERENCE SIGNS LIST

1: Unit cell
2: Si substrate
3: Thin gate film
4: Insulating film
5: Poly-Si channel
6: Insulating film
7: Hole
11: Top layer
12: Middle layer
13: Bottom layer
d: Recess amount

1. An etching solution composition, wherein the etching solution composition comprises (A) nitric acid, (B) acetic acid, (C) nitrilotris(methylene phosphonic acid), (D) a halogen compound, and (E) water.

2. The etching solution composition of claim 1, wherein the concentration of the halogen compound (D) is higher than 0.05 M based on the etching solution composition.

3. The etching solution composition of claim 1, wherein the etching solution composition further comprises (F) 1-hydroxyethane-1,1-diphosphonic acid.

4. The etching solution composition of claim 1, wherein the halogen compound (D) is a chloride.

5. The etching solution composition of claim 1, wherein the etching solution composition contains no peroxide.

6. The etching solution composition of claim 1, wherein the etching solution composition is for etching treatment of molybdenum or a metal containing molybdenum.

7. The etching solution composition of claim 1, which is for creating a pattern having a three-dimensional structure.

8. A method for forming a recess, wherein the method comprises a step of treating with the etching solution composition of claim 1.

9. An etching method using the etching solution composition of claim 1, wherein the temperature of the etching solution composition is 15° C. to 50° C.
